(19) United States
(12) Patent Application Publication
(10) Pub. No.: US 2010/0253876 A1
(43) Pub. Date: Oct. 7, 2010

(54) LIGHT EMITTING DEVICE AND DISPLAY DEVICE USING THE LIGHT EMITTING DEVICE AS A LIGHT SOURCE

(76) Inventors: Kyung-Sun Ryu, Suwon-si (KR); Hyeong-Rae Seon, Suwon-si (KR); Dong-Su Chang, Suwon-Si (KR)

Correspondence Address: CHRISTIE, PARKER & HALE, LLP, PO BOX 7068, PASADENA, CA, 91109-7068, US

(21) Appl. No.: 12/631,791

(22) Filed: Dec. 4, 2009

(30) Foreign Application Priority Data
Dec. 8, 2008 (KR) 10-2008-0124093

(51) Int. Cl. G02F 1/1335; H01L 33/08; G02F 1/13357

(52) U.S. Cl. 349/61; 257/88; 362/97.1; 257/E33.005

(57) ABSTRACT

A light emitting device includes: a first substrate and a second substrate, each of the first and second substrates having an active area and an inactive area surrounding the active area, the first substrate having recesses in a side of the first substrate facing the second substrate; cathode electrodes in the recesses and extending along a first direction; electron emission regions on the cathode electrodes; gate electrodes on the side of the first substrate, extending along a second direction crossing the first direction of the cathode electrodes, and having a mesh structure with openings formed therein; first spacers between the first and second substrates in the active area; and second spacers between the first and second substrates in the inactive area. The second spacers press the gate electrodes to the first substrate to fix them in place.

### CROSS-REFERENCE TO RELATED APPLICATIONS

This application claims priority to and the benefit of Korean Patent Application No. 10-2008-0124093, filed in the Korean Intellectual Property Office, on Dec. 8, 2008, the entire content of which is incorporated herein by reference.

### BACKGROUND

1. Field

The described technology relates generally to a light emitting device. More particularly, the described technology relates generally to an electron emission unit and spacers of a light emitting device. Additionally, the described technology relates generally to a display device having a light emitting device.

2. Description of the Related Art

In the context of the present description, a light emitting device refers to a device capable of recognizing emission of light when viewed from outside. In one embodiment, a light emitting device includes a front substrate on which a phosphor layer and an anode electrode are formed and a rear substrate on which electron emission regions and driving electrodes are formed. The front and rear substrates are bonded together at their edge portions by a sealing member to form one body, and then the inner space is evacuated to form a vacuum chamber.

Typically, the driving electrodes include cathode electrodes and gate electrodes. The gate electrodes are formed in a direction crossing the cathode electrodes and positioned on the cathode electrodes with an insulating layer interposed therebetween. Openings are formed in the gate electrodes and the insulation layer at crossing regions of the cathode electrodes and the gate electrodes, and electron emission regions are formed inside the openings of the insulation layer above the cathode electrodes. The driving electrodes and the electron emission regions constitute an electron emission unit.

An electron emission unit having the above structure can be manufactured through a plurality of thin film and/or thick film processes. That is, a suitable method for manufacturing an electron emission unit includes the steps of: \textcircled{1} forming cathodes by coating and patterning a metal film on a substrate by a thin film process, such as sputtering or vacuum deposition; \textcircled{2} forming an insulation layer by applying, drying, and firing an insulation material on the cathodes by a thick film process, such as screen printing; \textcircled{3} forming gate electrodes by coating and patterning a metal film on the insulation layer again by a thin film process; \textcircled{4} forming openings by wet-etching part of the gate electrodes and insulation layer; and \textcircled{5} forming electron emission regions by screen-printing a paste mixture containing an electron emission material inside the openings of the insulation layer and performing drying, baking, and surface activation processes.

The electron emission unit having the above structure is relatively complicated to manufacture because it is very important to align members formed in each manufacturing step with members formed in the preceding step, which requires additional labor, and increases manufacturing time and cost.

Also, in the above electron emission unit, an initial diffusion angle of an electron beam is relatively large when electrons are emitted from the electron emission regions. Therefore, when electrons pass through the openings of the insulation layer, some collide with and electrically charge side walls of the insulation layer. The electrical charging of the insulation layer decreases the withstand voltage characteristics of the cathode electrodes and gate electrodes, thereby significantly deteriorating the driving stability of the light emitting device.

The above information disclosed in this Background section is only for enhancement of understanding of the background of the described technology and therefore it may contain information that does not form the prior art that is already known in this country to a person of ordinary skill in the art.

### SUMMARY OF THE INVENTION

An aspect of an embodiment of the present invention is directed toward a light emitting device having a simplified manufacturing process due to improvement of a structure of an electron emission unit, having a reduced manufacturing cost, and/or having an increased driving stability due to improvement of the withstand voltage characteristics of cathode electrodes and gate electrodes, and a display using the light emitting device as a light source.

Furthermore, aspects of embodiments of the present invention are directed toward a light emitting device that does not suffer from non-uniform electron emission and whose gate electrodes can be easily fixed, and a display using the light emitting device as a light source.

In an exemplary embodiment, a light emitting device includes: a first substrate and a second substrate, each of the first and second substrates having an active area and an inactive area surrounding the active area, the first substrate having a plurality of recesses in a side of the first substrate facing the second substrate; a plurality of cathode electrodes in the recesses and extending along a first direction; a plurality of electron emission regions on the cathode electrodes; a plurality of gate electrodes on the side of the first substrate, extending along a second direction crossing the first direction of the cathode electrodes, and having a mesh structure with openings formed therein; a light emission unit on a side of the second substrate facing the first substrate; a plurality of first spacers between the first and second substrates in the active area; and a plurality of second spacers between the first and second substrates in the inactive area and pressing the gate electrodes to the side of the first substrate.

The second spacers may have a different shape from the first spacers. The first spacers may be formed in a pillar shape, and the second spacers may be formed in a bar shape. The first spacers may have a width that is greater than a gap between the gate electrodes and may overlap a part of the gate electrodes.

The second spacers may have a different shape than that of the first spacers. Each of the first spacers may have a pillar shape, and each of the second spacers may have a bar shape. Each of the first spacers may have a width greater than a gap between the gate electrodes and may overlap with a part of the gate electrodes.

The second spacers may extend along a width direction of the gate electrodes at both ends of the gate electrodes. Each of the second spacers may cross all of the gate electrodes. Alternatively, each of the second spacers may cross some of the gate electrodes, and at least two of the second spacers may be located side by side in the width direction of the gate electrodes.

The recesses may be deeper than the sum of the thickness of the cathode electrodes and the thickness of the electron emission regions.

In another exemplary embodiment, a display device includes a light emitting device, and a display panel located in front of the light emitting device and receiving light emitted from the light emitting device to display images. The light emitting device includes: a first substrate and a second substrate, each of the first and second substrates having an active area and an inactive area surrounding the active area, the first substrate having a plurality of recesses in a side of the first substrate facing the second substrate; a plurality of cathode electrodes in the recesses and extending along a first direction; a plurality of electron emission regions on the cathode electrodes; a plurality of gate electrodes on the side of the first substrate, extending along a second direction crossing the first direction of the cathode electrodes, and having a mesh structure with openings formed therein; a light emission unit on a side of the second substrate facing the first substrate; a plurality of first spacers between the first and second substrates in the active area; and a plurality of second spacers between the first and second substrates in the inactive area, having a different shape than that of the first spacers, and pressing the gate electrodes to the side of the first substrate.

The display panel may include first pixels and the light emitting device may include second pixels, wherein there may be fewer second pixels than first pixels. Each of the second pixels may emit light independently from each other in response to the gray level of the corresponding first pixels. The display panel may be a liquid crystal display panel.

### BRIEF DESCRIPTION OF THE DRAWINGS

FIG. 1 is a perspective view of part of a light emitting device according to a first embodiment.

FIG. 2 is a sectional view of part of the light emitting device according to the first embodiment.

FIG. 3 is a plan view showing a first substrate, gate electrodes, second spacers, and a sealing member in the structure of the light emitting device shown in FIG.

FIG. 4 is a sectional view showing a part of a light emitting device of a comparative example using an intermediate medium.

FIG. 5 is a perspective view schematically showing gate electrodes and first and second spacers in the structure of the light emitting device according to a second embodiment.

FIG. 6 is an exploded perspective view of a display according to one embodiment.

FIG. 7 is a sectional view of a part of the display panel shown in FIG. 6.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

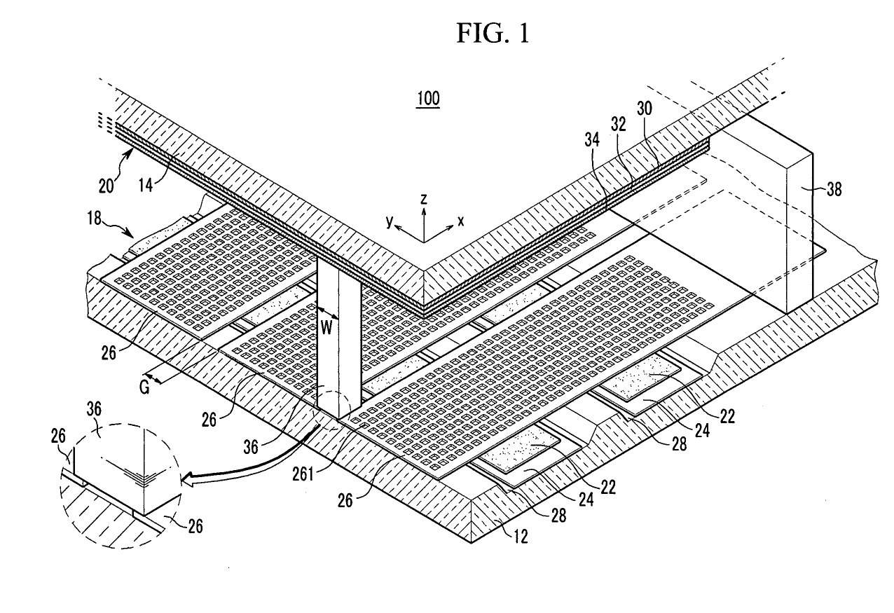

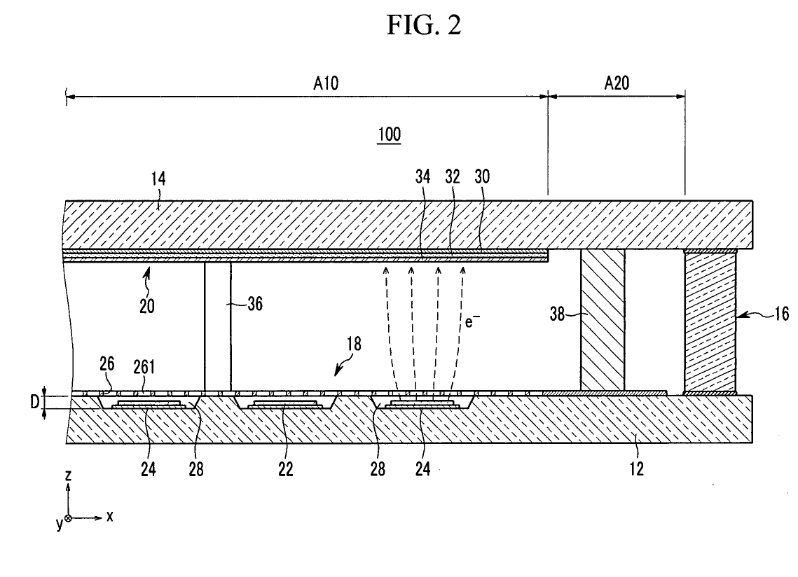

FIG. 1 and FIG. 2 are, respectively, a perspective view and a sectional view of a part of a light emitting device according to a first embodiment.

Referring to FIGS. 1 and 2, the light emitting device includes a first substrate 12 and a second substrate 14 that are disposed facing each other. A sealing member 16 is provided at the edge portions of the first and second substrates 12 and 14 to seal them together and thus form a vacuum chamber. The interior of the sealed vacuum chamber is evacuated and maintained at a pressure of about 10⁻⁶ Torr.

Of the first and second substrates 12 and 14, the areas inside of the sealing member 16 are divided into an active area A10 (see FIG. 2) substantially contributing to the emission of visible light and an inactive area A20 (see FIG. 2) surrounding the active area A10. An electron emission unit 18 for emitting electrons is provided at the active area A10 of the first substrate 12, and a light emission unit 20 for emitting visible light is provided at the active area A10 of the second substrate 14. The second substrate 14 on which the light emission unit 20 is located may be a front substrate of the light emitting device 100.

The electron emission unit 18 includes electron emission regions 22 and driving electrodes for controlling an electron emission amount of the electron emission regions 22. The driving electrodes include cathode electrodes 24 formed in a stripe pattern extending in a first direction (y-axis direction as indicated in the drawings) of the first substrate 12, and gate electrodes 26 formed in a stripe pattern extending in a second direction (x-axis direction as indicated in the drawings) crossing the first direction above the cathode electrodes 24.

In this exemplary embodiment, recesses 28 having a depth D (see FIG. 2) are formed on an inner surface of the first substrate 12 facing the second substrate 14 so that the cathode electrodes 24 are located on the bottom surfaces of the recesses 28. The recesses 28 may be formed by removing part of the first substrate 12 by a method such as etching or sand blasting, and are formed in a stripe pattern in the length direction of the cathode electrodes 24.

The recesses 28 are wider than the cathode electrodes 24, and have the depth D that is greater than the combined thickness of the cathode electrodes 24 and the electron emission regions 22. The recesses 28 may have vertical or sloped side walls. FIGS. 1 and 2 illustrate one example in which the recesses 28 have sloped side walls. The thickness of the first substrate 12 may be about 1.8 mm, the depth D of the recesses 28 may be about 40 μm, and the maximum width of the recesses may be between about 300 and about 600 μm.

The cathode electrodes 24 located on the bottom surfaces of the recesses 28, as seen from above, are located a certain or predetermined height difference below the upper surface (inner surface of the first substrate 12 where no recess 28 is formed) of the first substrate 12. Regions of the first substrate 12 located between the recesses 28 form relatively higher protruding portions, and these protruding portions function as a barrier for separating neighboring cathode electrodes 24 from each other.

The electron emission regions 22 may be formed on the cathode electrodes in a stripe pattern parallel to the cathode electrodes 24. Alternatively, the electron emission regions 22 may be partially formed on the cathode electrodes 24, corresponding to crossing areas of the cathode electrodes 24 and the gate electrodes 26. FIG. 1 illustrates one example in which the electron emission regions 22 are formed in a stripe pattern.

The electron emission regions 22 may be formed by a thick film process such as screen printing. That is, the electron emission regions 22 may be formed by the processes of: \textcircled{1} screen-printing a paste mixture containing an electron emission material on the cathode electrodes 24; \textcircled{2} drying and firing the printed mixture; and \textcircled{3} activating the surface of the electron emission regions 22 so as to expose the electron emission material to the surface of the electron emission regions 22.

The surface activation process may be performed by an operation of attaching an adhesive tape onto the first substrate 12 and then removing it. This is carried out before fixing the gate electrodes 24 onto the first substrate 12. Through the surface activation process, part of the surface of the electron emission regions 22 may be removed and electron emission materials, such as carbon nanotubes, may be raised substantially vertical with respect to the surface of the electron emission regions 22.

As the depth D of the recesses 28 is greater than the combined thickness of the cathode electrodes 24 and the electron emission regions 22, the electron emission regions 22 are also located a certain or predetermined height difference below the upper surface of the first substrate 12.

The cathode electrodes 24 are formed through a suitable thin film process and/or a suitable thick film process. In one embodiment of the present invention, the gate electrodes 26 are formed from a metal plate of a certain or predetermined thickness to have a mesh structure with openings 261 formed therein for transmitting an electron beam. For example, the gate electrodes 26 may be manufactured by the steps of cutting a metal plate having a given size into a stripe shape and then forming openings 261 on the metal plate by a method such as etching.

The gate electrodes 26 may have openings 261 at regions between the cathode electrodes 24, i.e., regions facing the first substrate 12, as well as at regions facing the cathode electrodes 24, based on a state in which the gate electrodes 26 are installed on the first substrate 12.

The gate electrodes 26 of this type, excluding both ends, form a mesh structure. This provides the benefit of not having to consider alignment characteristic with the cathode electrodes 24 when fixing the gate electrodes 26 onto the first substrate 12. The gate electrodes 26 may be made of a nickel-iron alloy or other metal material, and may have a thickness of about 50 μm and a width of about 10 mm.

The gate electrodes 26 are spaced apart and fixed to the upper surface of the first substrate 12 in a direction crossing the cathode electrodes 24. Here, as the cathode electrodes 24 and the electron emission regions 22 are located in the recesses 28 of the first substrate 12, insulation between the cathode electrodes 24 and the gate electrodes 26 can be ensured automatically by only fixing the gate electrodes 26 to the upper surface of the first substrate 12.

In the above-described structure, one crossing region of the cathode electrodes 24 and the gate electrodes 26 may correspond to one pixel area of the light emitting device 100, or two or more crossing regions may correspond to one pixel area of the light emitting device 100. In the latter case, the cathode electrodes 24 in the same pixel area are applied with the same driving voltage, and the gate electrodes 26 in the same pixel area are also applied with the same driving voltage.

Next, the light emission unit 20 includes an anode electrode 30 formed on an inner surface of the second substrate 14, a phosphor layer 32 located on one surface of the anode electrode 30, and a reflection layer 34 covering the phosphor layer 32.

The anode electrode 30 is formed of a transparent conductive material such as indium tin oxide (ITO) so that visible light emitted from the phosphor layer 32 can transmit through the anode electrode 30. The anode electrode 30 is an acceleration electrode that receives a high voltage (i.e., anode voltage) of thousands of volts or more to place the phosphor layer 32 at a high potential state so as to attract an electron beam.

The phosphor layer 32 may be formed of a mixture of red, green, and blue phosphors, which can collectively emit white light. The phosphor layer 32 may be formed on the entire active area A10 of the second substrate 14, or may be divided into a plurality of sections corresponding to the pixel areas. FIGS. 1 and 2 illustrate a case where the phosphor layer 32 is formed on the entire active area of the second substrate 14.

The reflection layer 34 may be an aluminum layer having a thickness of several thousands of angstroms (Å) and including a plurality of tiny holes for passing an electron beam. The reflection layer 34 functions to enhance the luminance of the light emitting device 100 by reflecting visible light emitted from the phosphor layer 32 to the first substrate 12 toward the second substrate 14. The anode electrode 30 described above can be eliminated, and the reflection layer 34 can receive the anode voltage and function as the anode electrode.

First spacers 36 having a pillar shape are disposed in the active area A10 between the first and second substrates 12 and 14. The first spacers 36 function to withstand a compression force applied to the vacuum chamber and to uniformly maintain the gap between the first and second substrates 12 and 14. The first spacers 36 are formed in a cylinder shape, a rectangular pillar shape, or some other pillar shape. FIGS. 1 and 2 illustrate the first spacers 36 as having a rectangular pillar shape by way of example.

The light emitting device 100 having the above-described structure is driven when a scan driving voltage is applied to either the cathode electrodes 24 or the gate electrodes 26, a data driving voltage is applied to the other electrodes 24 or 26, and an anode voltage of thousands of volts or more is applied to the anode electrode 30.

Electric fields are formed around the electron emission regions 22 at the pixels where the voltage difference between the cathode electrodes 24 and the gate electrodes 26 is greater than a threshold value, and thus electrons are emitted from the electron emission regions 22. The emitted electrons, attracted by the anode voltage applied to the anode electrode 30, collide with a corresponding portion of the phosphor layer 32, thereby exciting the phosphor layer 32. A luminance of the phosphor layer 32 for each pixel corresponds to an electron beam emission amount of the corresponding pixel.

In the above-described driving process, as the gate electrodes 26 are disposed directly above the electron emission regions 22, electrons emitted from the electron emission regions 22 pass through the openings 261 of the gate electrodes and reach the phosphor layer 32 with reduced or minimal beam diffusion. Accordingly, the light emitting device 100 of this exemplary embodiment can effectively suppress electrical charging of the side walls of the recesses 28 by reducing the initial diffusion angle of an electron beam.

As a result, the light emitting device 100 of this exemplary embodiment can stabilize driving by increasing withstand voltage characteristics of the cathode electrodes 24 and the gate electrodes 26, and can achieve high luminance by applying a voltage of 10 kV or more, and, in one embodiment, between about 10 and about 15 kV, to the anode electrode 30.

Additionally, the light emitting device 100 of this exemplary embodiment enables a manufacturing process to be simplified because a thick film process for forming an insulation layer and a thin film process for forming gate electrodes as in the conventional art may be omitted. Further, as described above, it is not necessary to consider alignment characteristics with the cathode electrodes 24 when disposing the gate electrodes 26 on the first substrate, thus making manufacturing easier.

Moreover, since the gate electrodes 26 are disposed after the electron emission regions 22 are formed, it is possible to avoid the problem of a conductive electron emission material short circuiting the cathode electrodes 24 and the gate electrodes 26 during formation of the electron emission regions 22 as can occur in the conventional art.

In the above-described structure, both ends of the gate electrodes 26 are extended to the inactive area A20, and particularly, one end thereof is extended through the inactive area A20 outside of the sealing member 16 to form terminals. Such gate electrodes 26 are pressed by second spacers 38 located at the inactive area A20 and fixed to the first substrate 12. The second spacers 38 are formed in a bar shape, and have the same height as the first spacers 36.

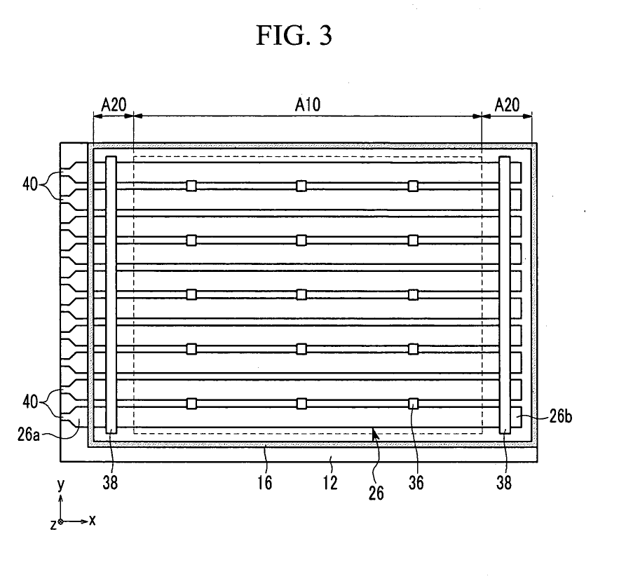

FIG. 3 is a plan view showing the first substrate 12, the gate electrodes 26, the second spacers 38, and the sealing member 16 in the structure of the light emitting device 100 shown in FIG. 1.

Referring to FIG. 3, the gate electrodes 26 are provided with terminals 40 for applying a voltage to first ends 26a, and the terminals 40 are arranged in parallel along the periphery of the first substrate 12. The sealing member 16 is disposed on the thus-aligned gate electrodes 26. The sealing member 16 is disposed crossing the gate electrodes 26 so as to expose the terminals 40 out of a region defined by the sealing member 16. As a result, the gate electrodes 26 are pressed at the first ends 26a by the sealing member 16, and are fixed to the first substrate 12 by the bonding force and compressing force of the sealing member 16.

Further, the second spacers 38 are located over and across the gate electrodes 26 in the inactive area A20 around the first ends 26a and the active area A10 around second ends 26b. Thus, the second spacers 38 press all of the gate electrodes 26 and fix them in place on the first substrate 12.

In this exemplary embodiment, each of the second spacers 38 is formed as a long bar type, crossing all of the gate electrodes 26. Accordingly, both ends of the gate electrodes 26 are pressed by the second spacers 38 and hence are firmly fixed onto the first substrate 12 without a medium such as an adhesive.

In addition, the first spacers 36 located in the active area A10 may have a structure wherein they do not press the gate electrodes 26 as they are located between the gate electrodes 26, or a structure wherein they press the gate electrodes 26 as they overlap with part of the gate electrodes 26. FIG. 1 illustrates the latter case.

Referring to FIG. 1, the first spacers 36 may have a width W that is greater than the gap G between the gate electrodes 26, and may be located between two neighboring gate electrodes 26 to overlap with a part of the gate electrodes 26. Accordingly, the gate electrodes 26 are pressed by the first spacers 36 in the active area A10 and by the second spacers 38 in the inactive area A20, thereby further improving adherence to the first substrate 12. The first and second spacers 36 and 38 may be fixed onto the first substrate 12 by an adhesive, which is not shown.

In this way, in the light emitting device 100 of this exemplary embodiment, the second spacers 38 are disposed in the inactive area A20 so as to press the gate electrodes 26 to fix them in place on the first substrate 12. In this structure, the second spacers 38 are not affected by a spacer limiting condition within the active area A10, thus making it easier to choose the shape of the second spacers 38 and simplifying a spacer loading process by use of bar-shaped second spacers 38.

Additionally, the gate electrodes 26 are kept from moving or being shaken in a subsequent process or after completion of the product, thereby preventing (protecting from) an electrical short circuit between the gate electrodes 26.

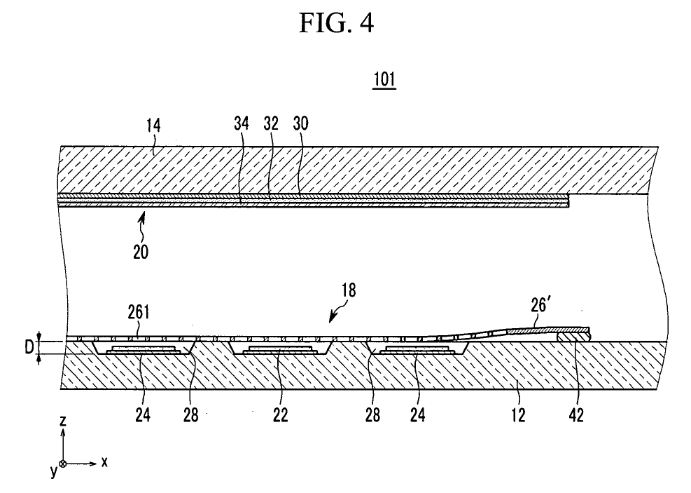

The light emitting device 100 with the above-described structure is in sharp contrast to a structure using an intermediate medium 42 (medium located between the first substrate 12 and gate electrodes 26′, for fixing the gate electrodes 26′) such as an adhesive, as illustrated in FIG. 4. FIG. 4 is a sectional view showing a part of a light emitting device of a comparative example using an intermediate medium. In the structure of FIG. 4, the same members as in the previous embodiment are designated by the same reference numerals.

Referring to FIG. 4, a light emitting device 101 of the comparative example includes the intermediate medium 42 located under the gate electrodes 26′ at one end of the gate electrodes 26′. The intermediate medium 42 may be a frit glass adhesive layer.

In this structure, a space is formed between the first substrate 12 and the gate electrodes 26 by the intermediate medium 42 having a certain or predetermined thickness, and accordingly the gate electrodes 26′ are deformed. Thus, the gate electrodes 26′ are located at a much greater height from the electron emission regions 22 adjacent to the intermediate medium 42.

Consequently, the electron emission regions 22 (electron emission regions 22 located at the far right side in FIG. 4) show a lower electron emission amount than the other electron emission regions 22, thus causing non-uniform electron emission and reducing reliability of a resultant product. On the contrary, the light emitting device 100 of the exemplary embodiment does not suffer from non-uniform electron emission since it does not use the intermediate medium 42.

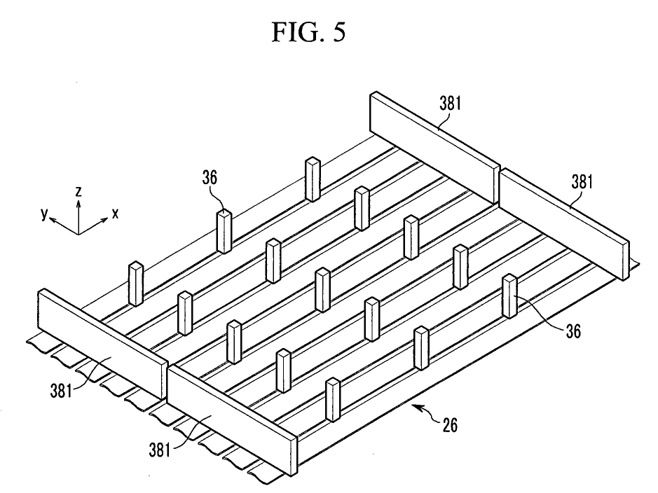

FIG. 5 is a perspective view schematically showing gate electrodes and first and second spacers in the structure of a light emitting device according to a second embodiment.

Referring to FIG. 5, the light emitting device of this exemplary embodiment has the same configuration as the light emitting device of the previous embodiment, except that two or more second spacers 381 are disposed around first ends and second ends, respectively, of the gate electrodes 26. The same members as in the first embodiment are designated by the same reference numerals.

In this exemplary embodiment, the respective second spacers 381 cross some of the gate electrodes 26 and are located side by side and spaced apart from one another in a width direction (y-axis direction as indicated in the drawing) of the gate electrodes 26. Such alignment of the second spacers 381 may be usefully applicable to a large-area light emitting device.

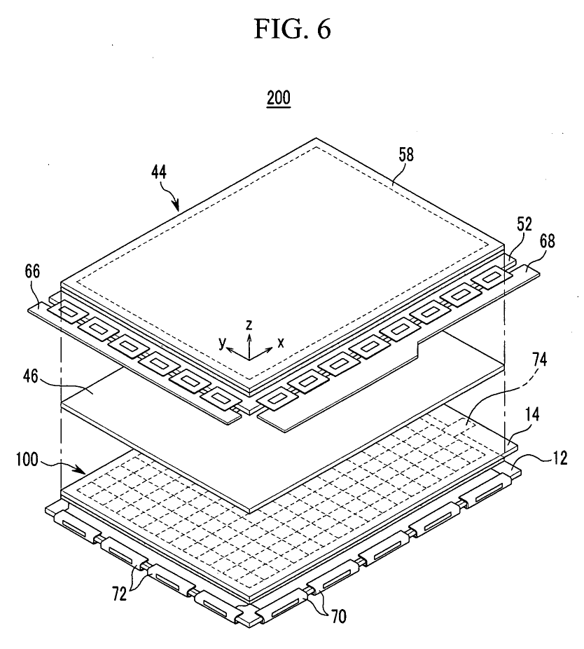

FIG. 6 is an exploded perspective view of a display device 200 according to an embodiment.

Referring to FIG. 6, the display device 200 includes a light emitting device 100 and a display panel 44 located in front of the light emitting device 100. The light emitting device 100 is the light emitting device of the previous first or second embodiment, and functions as a light source in the display 200. The display panel 44 may be a transmissive or semi-transmissive liquid crystal display panel. A diffuser 46 for uniformly diffusing light emitted from the light emitting device 100 may be located between the light emitting device 100 and the display panel 44.

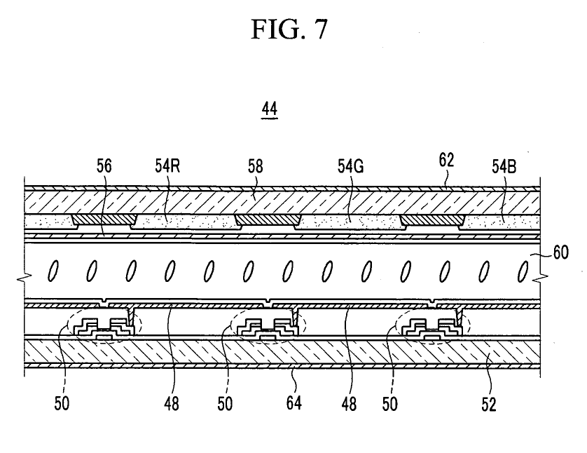

FIG. 7 is a sectional view of a part of the display panel shown in FIG. 6, which illustrates a transmissive liquid crystal display panel by way of example. The case where the display panel 44 is a transmissive liquid crystal display panel is described in more detail with reference to FIG. 7.

Referring to FIG. 7, the display panel 44 includes a lower substrate 52 on which pixel electrodes 48 and thin film transistors 50 are formed, an upper substrate 58 on which color filter layers 54R, 54G, and 54B and a common electrode 56 are formed, and a liquid crystal layer 60 injected between the upper and lower substrates 58 and 52. Polarizing plates 62 and 64 are attached on a top surface of the upper substrate 58 and a bottom surface of the lower substrate 52 to polarize light passing through the display panel 44.

A pixel electrode 48 is arranged for each sub-pixel, and driving of the pixel electrodes 48 is controlled by the thin film transistors 50. The pixel electrodes 48 and the common electrode 56 are formed of a transparent conductive material. The color filter layers 54R, 54G, and 54B include a red filter layer 54R, a green filter layer 54G, and a blue filter layer 54B arranged to correspond to respective sub-pixels.

When the thin film transistor 50 of a specific sub-pixel is turned on, an electric field is formed between the pixel electrode 48 and the common electrode 56. The arrangement angle of liquid crystal molecules is varied by this electric field, and the light transmittance is varied in accordance with the varied arrangement angle. The display panel 44 can control the luminance and color for each pixel by this procedure.

Referring again to FIG. 6, reference numeral 66 represents a gate circuit board assembly for transmitting gate driving signals to gate electrodes of the thin film transistors 50, and reference numeral 68 represents a data circuit board assembly for transmitting data driving signals to source electrodes of the thin film transistors 50.

The light emitting device 100 includes a plurality of pixels, the number of which is less than the number of pixels of the display panel 44 so that one pixel of the light emitting device 100 corresponds to two or more pixels of the display panel 44. Each pixel of the light emitting device 100 may emit light in response to gray levels of the corresponding pixels of the display panel 44. In one example, each pixel of the light emitting device 100 may emit light in response to the highest gray level of the corresponding pixels of the display panel 44. The light emitting device 100 can represent gray levels of a gray scale between 2 and 8 bits at each pixel.

For convenience, the pixels of the display panel 44 are referred to as first pixels and the pixels of the light emitting device 100 are referred to as second pixels. The various first pixels corresponding to one second pixel are referred to as a first pixel group.

In a driving process of the light emitting device 100, a signal control unit that controls the display panel 44 \textcircled{1} detects the highest gray level of the first pixel group, \textcircled{2} operates a gray level required for emitting light from the second pixel in response to the detected high gray level and converts the operated gray level into digital data, \textcircled{3} generates a driving signal of the light emitting device 100 using the digital data, and \textcircled{4} applies the generated driving signal to the driving electrodes of the light emitting device 100.

The driving signal of the light emitting device 100 includes a scan driving signal and a data driving signal. The cathode electrodes or the gate electrodes (e.g., the gate electrodes) are applied with the scan driving signal and the other electrodes (e.g., the cathode electrodes) are applied with a data driving signal.

Scan and data circuit board assemblies for driving the light emitting device 100 may be located on a rear surface of the light emitting device 100. In FIG. 6, reference numeral 70 represents first connectors for connecting the cathode electrodes 24 and the data circuit board assembly, and reference numeral 72 represents second connectors for connecting the gate electrodes 26 and the scan circuit board assembly. Reference numeral 74 represents a third connector for applying an anode voltage to the anode electrode 30.

When an image is displayed on the first pixel group, the corresponding second pixel of the light emitting device 100 emits light with a certain or predetermined gray level by synchronizing with the first pixel group. That is, the light emitting device 100 provides light of a high luminance to bright areas of a screen realized by the display panel 44, and provides light of a low luminance to dark areas thereof. As a result, the display device 200 of this exemplary embodiment can enhance the contrast ratio of the screen, thereby improving the display quality.

According to the exemplary embodiments, driving can be stabilized by increasing the withstand voltage characteristics of the cathode electrodes and the gate electrodes, and high luminance can be achieved by increasing the anode voltage. In addition, since a thick film process for forming an insulation layer and a thin film process for forming gate electrodes may be omitted, the manufacturing process of the light emitting device can be simplified, and manufacturing cost can be reduced.

Further, as the second spacers located in the inactive area are pressed, the gate electrodes can be firmly fixed onto the first substrate without using an intermediate medium such as an adhesive. The second spacers are not affected by a spacer limiting condition within the active area, thus making it easier to choose their shape and simplifying a spacer loading process by the use of bar-shaped second spacers 38.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A light emitting device comprising:
a first substrate and a second substrate, each of the first and second substrates having an active area and an inactive area surrounding the active area, the first substrate having a plurality of recesses in a side of the first substrate facing the second substrate;
a plurality of cathode electrodes in the recesses and extending along a first direction;
a plurality of electron emission regions on the cathode electrodes;
a plurality of gate electrodes on the side of the first substrate, extending along a second direction crossing the first direction of the cathode electrodes, and having a mesh structure with openings formed therein;
a light emission unit on a side of the second substrate facing the first substrate;
a plurality of first spacers between the first and second substrates in the active area; and
a plurality of second spacers between the first and second substrates in the inactive area and pressing the gate electrodes to the side of the first substrate.

2. The light emitting device of claim 1, wherein
the second spacers have a different shape than that of the first spacers.

3. The light emitting device of claim 2, wherein
each of the first spacers has a pillar shape, and each of the second spacers has a bar shape.

4. The light emitting device of claim 3, wherein
each of the first spacers has a width greater than a gap between the gate electrodes and overlaps with a part of the gate electrodes.

5. The light emitting device of claim 1, wherein
the second spacers extend along a width direction of the gate electrodes at both ends of the gate electrodes.

6. The light emitting device of claim 5, wherein
each of the second spacers crosses all of the gate electrodes.

7. The light emitting device of claim 5, wherein
each of the second spacers crosses some of the gate electrodes, and at least two of the second spacers are located side by side in the width direction of the gate electrodes.

8. The light emitting device of claim 1, wherein
the recesses are deeper than that of the sum of the thickness of the cathode electrodes and the thickness of the electron emission regions.

9. A display device, comprising:
a light emitting device; and
a display panel in front of the light emitting device and for receiving light emitted from the light emitting device to display images,
wherein the light emitting device comprises:
a first substrate and a second substrate, each of the first and second substrates having an active area and an inactive area surrounding the active area, the first substrate having a plurality of recesses in a side of the first substrate facing the second substrate;
a plurality of cathode electrodes in the recesses and extending along a first direction;
a plurality of electron emission regions on the cathode electrodes;
a plurality of gate electrodes on the side of the first substrate, extending along a second direction crossing the first direction of the cathode electrodes, and having a mesh structure with openings formed therein;
a light emission unit on a side of the second substrate facing the first substrate;
a plurality of first spacers between the first and second substrates in the active area; and
a plurality of second spacers between the first and second substrates in the inactive area and pressing the gate electrodes to the side of the first substrate.

10. The display device of claim 9, wherein
the second spacers have a different shape than that of the first spacers.

11. The display device of claim 10, wherein
each of the first spacers has a pillar shape, and each of the second spacers has a bar shape.

12. The display device of claim 11, wherein
each of the first spacers has a width greater than a gap between the gate electrodes and overlaps with a part of the gate electrodes.

13. The display device of claim 11, wherein
the second spacers extend along a width direction of the gate electrodes at both ends of the gate electrodes.

14. The display device of claim 13, wherein
each of the second spacers crosses all of the gate electrodes.

15. The display device of claim 13, wherein
each of the second spacers crosses some of the gate electrodes, and at least two of the second spacers are located side by side in the width direction of the gate electrodes.

16. The display device of claim 10, wherein
the recesses are deeper than that of the sum of the thickness of the cathode electrodes and the thickness of the electron emission regions.

17. The display device of claim 9, wherein
the display panel comprises a plurality of first pixels and the light emitting device comprises a plurality of second pixels, and the second pixels are fewer in number than that of the first pixels, and
the second pixels are configured to emit light independently of each other in response to the gray levels of the corresponding first pixels.

18. The display device of claim 17, wherein
the display panel is a liquid crystal display panel.
